(19) United States
(12) Patent Application Publication
(10) Pub. No.: US 2011/0273851 A1
(43) Pub. Date: Nov. 10, 2011

(54) CIRCUIT BOARD, CIRCUIT MODULE, AND ELECTRONIC DEVICE PROVIDED WITH CIRCUIT MODULE

(75) Inventor: Seiji Yamaguchi, Shizuoka (JP)

(73) Assignee: PANASONIC CORPORATION, Osaka (JP)

(21) Appl. No.: 13/145,289

(22) PCT Filed: Nov. 6, 2009
(86) PCT No.: PCT/JP2009/005909

§ 371 Date: Jul. 19, 2011

(30) Foreign Application Priority Data
Jan. 20, 2009 (JP) 2009-010274

(51) Int. Cl. H05K 7/00

(52) U.S. Cl. 361/746

(57) ABSTRACT

A circuit board includes a substrate having a first surface and a second surface on an opposite side of the first surface. A hole is provided in the substrate so as to penetrate from the first surface to the second surface. A recess portion is formed in the second surface and has a bottom larger than a cross-section area of the hole. The hole is exposed on the bottom of the recess portion.

### TECHNICAL FIELD

The present invention relates to a circuit board on which various kinds of electronic components are mounted and then sealed with resin, a circuit module, and an electronic device provided with the circuit module.

### BACKGROUND ART

Various circuit boards on which various kinds of electronic components are mounted then molded with a resin have been proposed and developed. A method for sealing semiconductor elements with a resin is first described.

First, as shown in FIG. 5, a semiconductor element 100 having bump electrodes is mounted on a circuit board 200 by flip chip thereby connected to electrodes on the circuit board 200 by a solder material 101, etc. Next, as shown in FIG. 6, a sealing resin 300, such as an epoxy-based resin and a silicon-based resin, is supplied and filled in a gap between the semiconductor element 100 and the circuit board 200 by capillarity.

Subsequently, the filled resin 300 is thermally cured, whereby a semiconductor device is completed.

However, according to the related-art manufacturing method, air bubbles 301 may remain in the gap in a process of filling the sealing resin 300 in the gap between the semiconductor element 100 and the circuit board 200, as shown in FIG. 7. The air bubbles 301 causes a leak current failure between semiconductor elements and also a contact failure due to corrosion of the electrode of the semiconductor element, which is a cause of considerable deterioration of reliability of the semiconductor device.

Therefore, as shown in FIG. 8, there is proposed a method for manufacturing a semiconductor device (see, for example, Patent Document 1) using a circuit board 400 including air vent through holes 401 for air vent so as to provide the method in which air bubbles from do not remain in a gap between the semiconductor element 100 and the circuit board 400 at a resin seal process and also in which leaking of the sealing resin 300 is prevented.

### RELATED ART DOCUMENTS

### Patent Documents

Patent Document 1: JP-A-6-204272

### SUMMARY OF THE INVENTION

### Problem to be Solved by the Invention

However, even when resin sealing is performed according to such a method, if there is a little of sealing resin 300 leaked from a lower surface of the circuit board 400 through the air vent through holes 401, the leaked and cured resin forms irregularities on the lower surface of the circuit board 400. Therefore, for example, for a portable phone in which an electronic component, such as a liquid crystal display device, is mounted directly on the lower surface of the circuit board 400 in order to reduce a thickness thereof, the irregularities may cause various inconveniences to the electronic component, such as the liquid crystal display device. Under the circumstance, development of a technique for preventing leakage and spread of a sealing resin in the circuit board has been demanded.

An object of the present invention is to provide a circuit board capable of preventing leakage and spread of a sealing resin, a circuit module, and an electronic device provided with the circuit module.

### Means for Solving the Problem

A circuit board of the present invention includes: a substrate having a first surface and a second surface on an opposite side of the first surface, wherein a hole is provided in the substrate so as to penetrate from the first surface to the second surface, wherein a recess portion is formed in the second surface and which has a bottom larger than a cross-section area of the hole, and wherein the hole is exposed on the bottom of the recess portion.

With this configuration, the recess portion can trap the resin which is leaked from the hole of the substrate and may spread on the second surface, whereby the resin can be efficiently prevented from protruding outward from the second surface of the substrate.

A circuit module of the present invention includes: a mounting component mounted on the first surface of the circuit board; and a resin covering the mounting component, wherein the hole is formed in a region of the first surface which opposes the mounting component.

With this configuration, the recess portion can trap the resin which is leaked from the hole of the substrate and may spread on the second surface, whereby the leakage of the resin from the second surface of the substrate can be efficiently prevented.

A electronic device of the present invention includes the circuit board or the circuit module.

With the configuration, for example, the recess portion can trap the resin used for sealing the mounting component mounted on the first surface of the substrate which is leaked from the hole of the substrate which may spread on the second surface, whereby the leakage of the resin from the second surface of the substrate can be efficiently prevented. Consequently, adverse influence to an electronic device due to the leaked resin (e.g., occurrence of a fracture or break in the electronic device or deterioration of quality of the electronic device) can be prevented.

### Advantages of the Invention

In the circuit board of the present invention, the hole is exposed on the bottom of the recess portion. With this configuration, even when the resin is leaked from the hole of the circuit board, the recess portion traps the leaked resin, whereby the resin can be prevented from spreading and protruding. Therefore, it is possible to prevent the resin from protruding outward from the second surface of the circuit board.

### BRIEF DESCRIPTION OF THE DRAWINGS

FIG. 1 is a cross sectional view showing a circuit module of a first embodiment of the present invention.

FIG. 2 is a diagram showing a bottom of the circuit module shown in FIG. 1.

FIG. 3 is a cross sectional view taken along line III-III shown in FIG. 2.

FIG. 4 is a cross sectional view showing an electronic device having the circuit module of the present invention.

FIG. 5 is a diagram showing a subsequent process of a method for sealing a semiconductor element by means of a related art resin.

FIG. 6 is a diagram showing inconvenience caused by the method for sealing a semiconductor element by means of the related art resin.

FIG. 7 is a diagram showing another related art resin sealing method.

FIG. 8 is a diagram showing another related art resin sealing method.

### MODE FOR CARRYING OUT THE INVENTION

An embodiment of the present invention will be described below in detail by reference to the accompanying drawings.

### First Embodiment

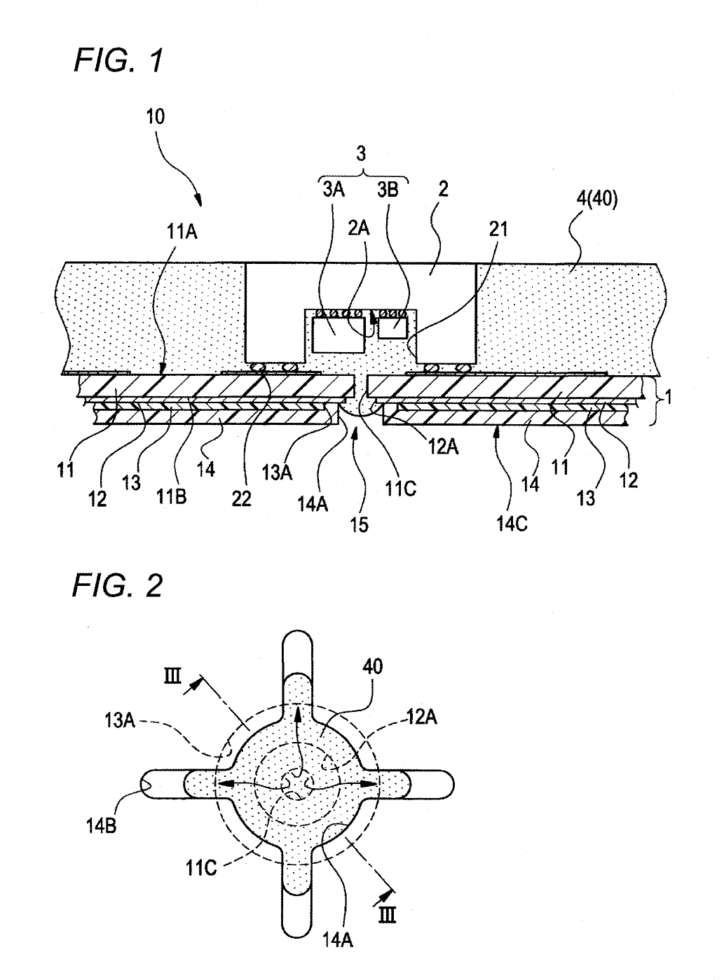

FIG. 1 shows a circuit module 10 of a first embodiment of the present invention. The circuit module 10 is provided in an unillustrated electronic device (a portable terminal device, e.g., a portable phone and a PHS) and includes a circuit board 1, a mounting component 2, an electronic component 3, and a resin portion 4.

The circuit board 1 described in detail later includes a printed board 11, and the like, and the mounting component 2 is mounted on the printed board 11.

The printed board 11 of the present embodiment has a second surface 11B (hereinafter called a “back surface”) that has a thickness, for example, of about 550 μm and that is on the other side of the first surface 11A (hereinafter called a “front surface”). A thin metal layer 12, for example, of about 18 μm (hereinafter called a “copper foil”) and a thin insulation resin layer 13, for example, of about 20 μm (hereinafter called a “resist”) are stacked on the second surface. In addition, a sheet having a thickness of about 100 μm, specifically, a Mylar sheet 14, is adhered to an outer surface of the resist 13 on the back surface 11B of the printed board 11.

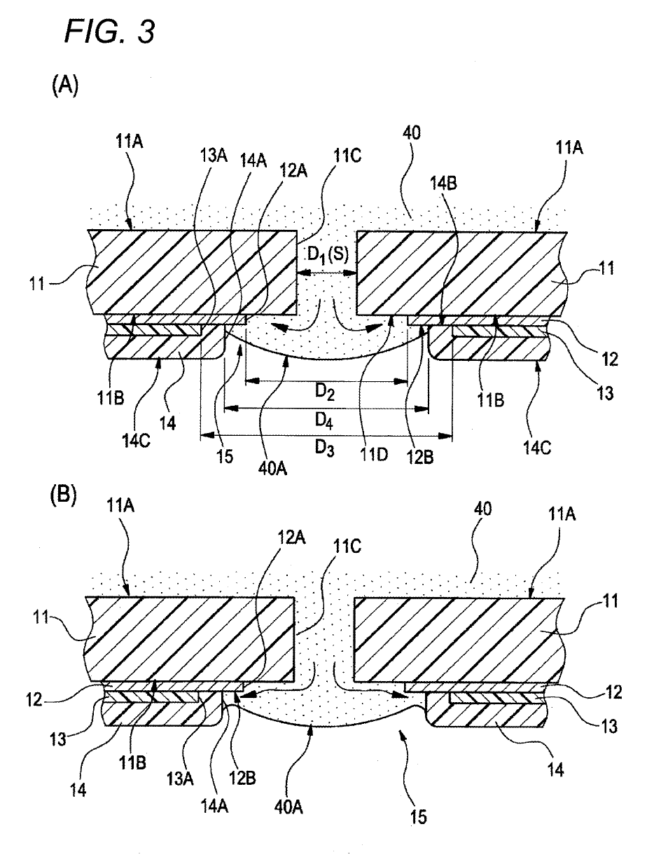

As shown in FIG. 3, a hole 11C having a diameter D₁ (of, for example, 250 μm) is opened in the printed board 11 so as to penetrate from the front surface 11A to the back surface 11B. The mounting component 2 is mounted on the front surface 11A so as to straddle the hole 11C. As shown in FIG. 2, the hole 11C of the present embodiment assumes a circular shape but may also assume, for example, a circle, an oval, a triangular shape, a square shape, and a polygonal shape. The following is a reason why the printed board 11 is provided with the hole 11C. In a case in which air (air bubbles) remains in a part of a resin 40 located in a cavity 21 of the mounting component 2 described later at the resin molding for creating the resin part 4, the air is thermally expanded during the thermal curing process subsequently performed and is ejected outside of the resin 40. The hole 11C is provided as a relief hole for the air (air bubbles) and a resin 40 so as to prevent such a trouble.

For this reason, a hole 12A, a hole 13A, and a hole 14A are formed in the copper foil 12, the resist 13, and the Mylar sheet 14 that are provided on the back surface 11B of the printed board 11, wherein these holes are opened at positions where the holes oppose the hole 11C. The holes, as a whole, define a through hole of the printed board 11. As described above, the hole 12A, the hole 13A, and the hole 14A are also opened in the copper foil 12, the resist 13, and the Mylar sheet 14 such that the holes are provided as relief holes for letting air (air bubbles) and the resin 40 escape to the back surface 11B of the printed board 11.

When predetermined pattern traces are formed in the copper foil 12 in advance, the hole 12A is concurrently opened in a position on the printed board 11 corresponding to the hole 11C. The hole 12A of the embodiment also assumes a complete circular shape with a diameter D₂ (D₁<D₂: see FIG. 3) which is larger than that of the hole 11C of the printed board 11.

As described above, the hole diameter D₂ of the hole 12A of the copper foil 12 is made larger than the hole diameter D₁ of the hole 11C of the printed board 11. As shown in FIG. 3, a periphery 11D enclosing the hole 11C of the printed board 11 and a periphery 12B enclosing the hole 12A of the copper foil 12 enclose the hole 11C of the printed board 11. Therefore, the printed board is configured in such a way that the resin 40 passed through and leaked out of the hole 11C of the printed board 11 can reach the periphery 11D and the periphery 12B.

The resist 13 has the hole 13A having a similar complete circular shape. A diameter D₃ of the hole 13A is made larger than the diameter D₁ of the hole 11C of the printed board 11 and the diameter D₂ of the hole of the copper foil 12 (see D₁<D₂<D₃: see FIG. 3). In particular, the hole diameter D₃ of the resist 13 is made larger than a hole diameter D₄ of the hole 14A of the Mylar sheet 14 to be described later.

The Mylar sheet 14 of the present embodiment is made of polyester that exhibits superior wettability with respect to the resin 40 of the resin portion 4. However, the sheet is not restricted to any specific type of material. Further, the hole 11C of the printed board 11, the hole 12A of the copper foil 12, and the hole 13A of the resists 13 can assume the same shape or different shapes. However, the Mylar sheet has the hole 14A that is partially cut into a predetermined shape (e.g., a circle, an oval, a triangular shape, a square shape, a polygonal shape, and the like).

The hole diameter D₄ of the hole 14A of the Mylar sheet 14 is made smaller than the hole diameter D₃ of the hole 12A of the copper foil 12 by an amount substantially corresponding to the thickness of the sheet (i.e., D₁<D₂<D₄<D₃, see FIG. 3). The Mylar sheet 14 is adhered to the resist 13 and the copper foil 12 in such a way that the periphery 12B enclosing the hole 12A of the copper foil 12 forms a bottom of the hole 14A of the Mylar sheet 14.

In short, in the present embodiment, a recess portion 15 leading to the hole 11C of the printed board 11 is made up of the periphery 11D of the printed board 11, the hole 12A and the periphery 12B of the copper foil 12, and the hole 14A of the Mylar sheet 14. Put another way, the hole 11C of the printed board 11 is exposed on a bottom of the recess portion 15 (the periphery 11D of the printed board 11). The recess portion 15 is formed as a recess in the circuit board 1 when viewed from the back surface side of the circuit board 1 (i.e., a position identical with the back surface 11B of the printed board 11). Moreover, the recess portion 15 is a sheet recess formed by removing a part of the Mylar sheet 14.

In the present embodiment, when the mounting component 2 is mounted on the front surface 11A of the printed board 11 of the circuit board 1 and when the gap between the printed board 11 and the mounting component 2 is filled with the resin 40, the resin 40 also enters the cavity 21, because the cavity 21 is formed between the mounting component 2 and the printed board 11. In the meantime, the printed board 11 is provided with the hole 11C penetrating from the front surface 11A to the back surface 11B in an area where the hole faces the cavity 21. Therefore, the resin 40 can run down the hole 11C, to thus flow to the back surface 11B of the printed board 11. However, the recess portion 15 is formed around the hole 11C of the back surface 11B. Therefore, the recess portion 15 traps the resin 40, thereby preventing the resin 40 from protruding a predetermined height or more in a direction outward from the back surface 11B.

Specifically, in the present embodiment, the recess portion 15 provided at a position corresponding to the hole in the back surface 11B of the printed board 11 is formed so that the resin 40 can run down and spread over walls of the recess portion by virtue of wettability. As shown in FIG. 3(A), the resin can be prevented from rising so as to protrude outward an outer surface 14C of the Mylar sheet 14.

In the embodiment, an inner end face making up an inner circumference of the hole 14A of the Mylar sheet 14 is fixed to a part of the periphery 12B enclosing the hole 12A of the copper foil 12, thereby assuring a surface area of the portion of the Mylar sheet 14 that makes up the hole 14A and that is also exposed on the recess portion. Put another way, the Mylar sheet 14 is caused to enter up to the hole 13A of the resist 13, thereby increasing a region of the Mylar sheet which contacts the resin 40 having passed through and leaked out the hole 11C of the printed board 11. Thus, a resin hold effect of the Mylar sheet 14 is enhanced to a much greater extent.

The hole 14A of the Mylar sheet 14 is arranged so as to enclose the hole 12A and the periphery 12B of the copper foil 12. The hole 12A of the copper foil 12 is arranged so as to enclose the periphery 11D and the hole 11C of the printed board 11. Therefore, the recess portion 15 has two bottoms (i.e., a two-step recess portion) of the periphery 12B and the periphery 11D and is provided so as to penetrate up to the back surface 11B of the printed board 11. Since the recess portion 15 is formed so as to have the two bottoms, the recess portion 15 exhibits a high effect of holding the resin 40.

Despite the fact that the resin 40 has leaked out of the hole 11C to the recess portion 15, an outer surface 40A of the resin exposed on the back surface is situated between the back surface 11B and the outer surface 14C of the Mylar sheet 14 because of action of the recess portion 15. Such a configuration shows that the resin 40 does not protrude out of the back surface of the circuit board 1 and teaches that the back surface of the circuit board 1 can be made flat.

In the present embodiment, the recess portion 15 is formed as a two-step recess portion as a result of provision of the Mylar sheet 14. However, the Mylar sheet 14 is not indispensable. When the Mylar sheet 14 is not provided, the recess portion 15 is made up of the periphery 11D of the printed board 11 and the hole 12A and the periphery 12B of the copper foil 12. In this case, the recess portion 15 is made in the form of a recess portion in a metal layer formed by removal of a part of the copper foil 12 or a recess portion in an insulation layer formed by removal of a part of the resist 13.

The Mylar sheet 14 does not need to be adhered to the entirety of the circuit board 1 (the printed board 11). The circuit board 1 can also be provided with an area where the Mylar sheet 14 is to be adhered and another area where the Mylar sheet 14 is not adhered.

The mounting component 2 is welded to the front surface 11A of the printed board 11 by means of solder (balls) 22, and the like. As shown in FIG. 1, the mounting component 2 has the cavity 21 facing the front surface 11A. The electronic component (a semiconductor chip) 3 (3A and 3B) is mounted on a mount surface 2A serving as a bottom of the cavity 21.

The electronic component (a semiconductor chip) 3 is protected in a state of being fully embedded in the resin 40 of the resin portion 4 that molds the mounting component 2 including the cavity 21 so as to fully cover the entire outer periphery of the mounting component 2.

The resin portion 4 of the present embodiment covers a substantially entirety of the front surface 11A of the printed board 11 as well as the mounting component 2 on the front surface 11A of the printed board 11 by use of an epoxy resin, or the like. The strength of the printed board 11 can be thereby enhanced. Hence, an unillustrated electronic device equipped with the circuit module 10 does not necessitate a chassis for reinforcing the printed board 11.

In addition, as shown in FIG. 2, a groove 14B can be radially formed around; in particular, the hole 14A of the Mylar sheet 14 that forms the outermost layer of the recess portion 15. Even when a part of the resin 40 leaks out of the hole 14A with such a configuration, the leak will enter deep along the groove 14B by means of capillarity. Hence, it is possible to effectively prevent the resin 40 from protruding outward from the outer surface 14C of the Mylar sheet 14.

When the wettability of the Mylar sheet 14 is high or when the viscosity of the resin 40 is low, an area of the resin contacting the surface of the Mylar sheet 14 increases, thereby assuring an increase in the quantity of resin trapped in the recess portion, as shown in FIG. 3(B). Hence, it more effectively prevents the resin from protruding outward from the outer surface 14C of the Mylar sheet 14.

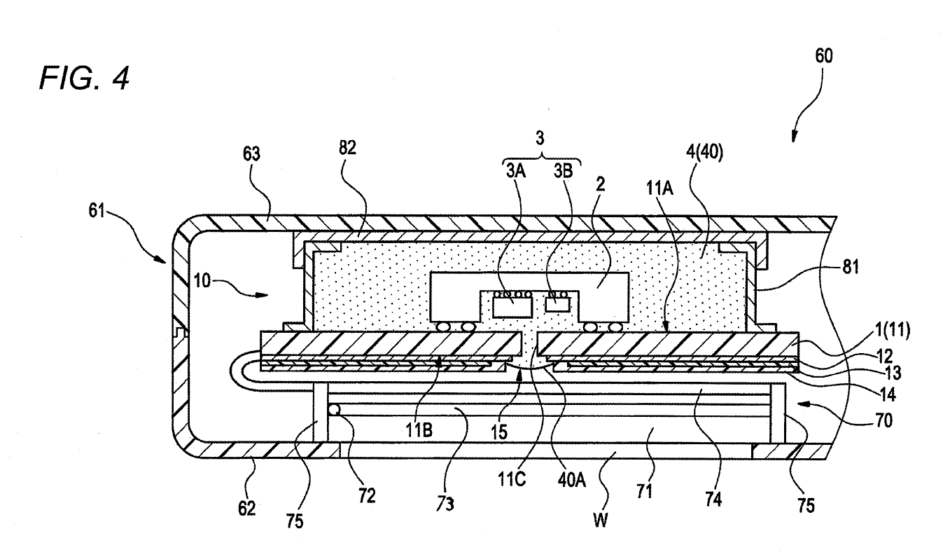

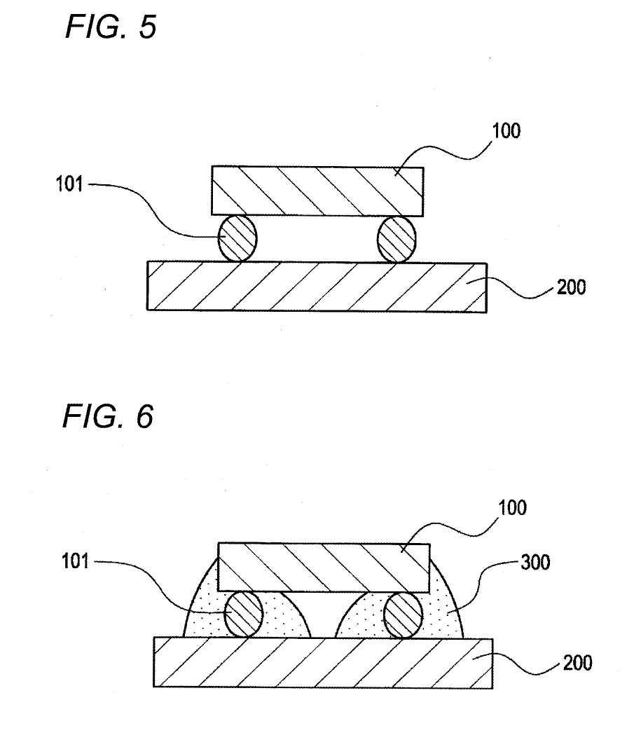

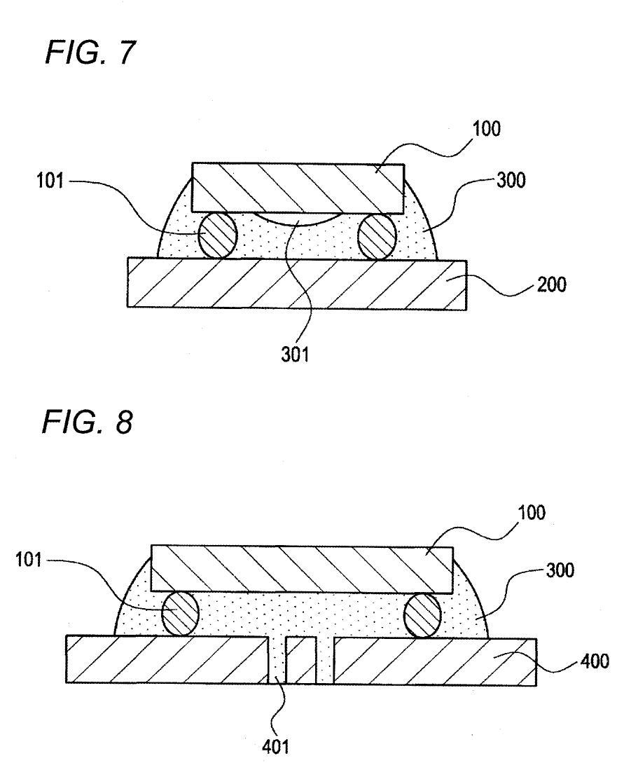

FIG. 4 shows a principal portion of an electronic device (i.e., a portable terminal device, like a portable phone, a PDA, and a PHS) 60 equipped with the circuit module 10 of the present embodiment. In the electronic device 60, the circuit module 10 and a liquid crystal display device 70 are provided in a housing 61.

The circuit module 10 has the circuit board 1, the mounting component 2, the electronic component 3, the resin portion 4, a frame body 81, and a cover body 82.

The hole 11C of the embodiment is also filled with the resin 40, and the resin 40 enters the recess portion 15 that is in mutual communication with the hole 11C, as well. The outer surface 40A on a bottom surface side of the resin 40, by means of which the resin 40 is exposed, is situated between the opening of the hole 11C on the back surface 11B of the printed board 11 and a bottom surface of the recess portion 15. Specifically, the resin 40 faces a reflection sheet 74 of the liquid crystal display device 70 but does not protrude out of the back surface (the outer surface 14C of the Mylar sheet 14) of the circuit board 1.

The housing 61 is configured while a first housing (hereinafter called a “front housing”) 62 and a second housing (hereinafter called a “back housing”) 63 remain bonded together. Further, the foregoing liquid crystal display device 70 is sandwiched and accommodated between the back surface of the circuit board 1 in the housing 61 (i.e., the outer surface 14C of the Mylar sheet 14) and the front housing 62. Further, the frame body 81 and the cover body 82 are provided, while being fitted together, so as to stretch across the front surface of the circuit board 11 in the housing 61 (i.e., the front surface 11A of the printed board 11) and the back housing 63.

Space defined between the frame body 81 and the cover body 82 and space surrounded by the front surface 11A of the printed board 11 and the back housing 63 are filled with the resin 40 making up the resin portion 4 so as to cover the mounting component 2 and the electronic component 3. Specifically, the resin 40 is fully charged so as to contact the frame body 81, the cover body 82, and the front surface 11A of the printed board 11, thereby covering the entire circumference of the electronic component 3.

A liquid crystal display (LCD) is used for the display device 70 in the present embodiment. The liquid crystal display (LCD) includes a liquid crystal cell 71, a light emitting block 72, a light guide plate 73, the reflection sheet 74 and a frame 75 for integrally stacking the liquid crystal cell 71, the light emitting block 72, the light guide plate 73 and the reflection sheet 74, which firmly contact and sandwiched between and firmly contacts the back surface of the circuit board 1 and a display window W of the front housing 62.

In the present embodiment, the backmost (a back surface) of the liquid crystal display device 70 is arranged in the vicinity of the back surface of the circuit board 1. However, as described above, the outer surface 40A of the resin 40 is situated between the opening of the hole 11C of the printed board 11 on the back surface 11B and the bottom surface of the recess portion 15. Therefore, the resin 40 will not squirt out of the recess portion 15 to inflict damage on the reflection sheet 74 put on the backmost of the liquid crystal display device 70. Further, the resin 40 does not press the reflection sheet 74, and hence a shadow, which deteriorates image quality, is not formed on a screen of the liquid crystal display. This obviates a necessity to additionally interpose a plane-shaped member between the reflection sheet 74 and the circuit board 1 to provide the reflection sheet 74 with a smoothed plane substantially free of irregularities. For example, this obviates a necessity for a plane-shaped member that supports the reflection sheet as a part of the frame of the display block. Alternatively, even when a plane-shaped member is provided, the reflection sheet 74 can be provided with a sufficiently-smoothed plane by use of an extremely thin plane-shaped member, for example, a thin film sheet. The display device of the present invention is not restricted to the liquid crystal display device of the present embodiment but can also be embodied, for example, as an organic EL display device.

In the present embodiment, the resin portion 4 and the display device 70 are disposed while remaining put on the respective surfaces of the circuit board 1. The resin portion 4, the circuit board 1, and the display device 70 reinforce each other, whereby structural strength of the electronic device is enhanced. Therefore, since a plane-shaped member having a thickness commensurate with spacing between the circuit board 1 and the display device 70 and rigidity is not required, the display device can be made slimmer correspondingly.

In the present embodiment, the mounting component 2 has a cavity. However, the present invention is applicable to a mounting component not having a cavity.

The embodiment of the present invention has been described thus far. However, the present invention is not limited to the matter described in connection with the embodiment and is slated to be susceptible to alterations and applications conceived by the person skilled in the art on the basis of the descriptions of the specification of the present patent application and the well known techniques, and the alterations and applications fall within a range where protection of the invention is sought.

The present patent application is based on Japanese Patent Application (Application No. 2009-010274) filed on Jan. 20, 2009, the entire subject matter of which is incorporated herein by reference.

### INDUSTRIAL APPLICABILITY

A circuit board or a circuit module of the present invention provides advantages of being able to prevent leakage and rise of a sealing resin, thereby avoiding occurrence of fracture of a display device, and is useful for an electronic device having a high definition display device, for example, of a portable terminal.

### DESCRIPTION OF REFERENCE SKINS

1 CIRCUIT BOARD
2 MOUNTING COMPONENT
3 ELECTRONIC COMPONENT
4 RESIN PORTION
10 CIRCUIT MODULE
11 PRINTED BOARD
11A FIRST SURFACE (FRONT SURFACE)
11B SECOND SURFACE (BACK SURFACE)
11C, 12A, 13A, 14A HOLE
12 METAL LAYER (COPPER FOIL)
13 INSULATION RESIN LAYER (RESIST)
14 SHEET (MYLAR SHEET)
21 CAVITY
40 RESIN
60 ELECTRONIC DEVICE (PORTABLE TERMINAL DEVICE)
61 HOUSING
70 DISPLAY DEVICE (LIQUID CRYSTAL DISPLAY DEVICE)
81 FRAME BODY
82 COVER BODY

1.-15. (canceled)

16. A circuit module comprising:
a circuit board comprising a substrate having a first surface and a second surface on an opposite side of the first surface;
a mounting component mounted on the first surface;
a resin filled between the substrate and the mounting component;
a hole formed in a region of the first surface which opposes the mounting component;
a predetermined sheet adhered to the second surface;
a sheet recess portion which is formed by removing a part of the predetermined sheet and which has a bottom larger than a cross-section area of the hole; and
a display device provided on the second surface of the circuit board,
wherein the hole is located on the bottom,
wherein the resin is filled in the hole, and an outer surface of the resin is located inside the sheet recess portion, and
wherein groove radially extending from the hole along the second surface.

17. The circuit module according to claim 16,
wherein the outer surface of the resin is situated inside the groove.

18. The circuit module according to claim 16,
wherein the second surface of the substrate has an area to which the sheet is to be adhered and another area where the sheet is not to be adhered.

19. The circuit module according to claim 16,
wherein a cavity is provided in a surface of the mounting component which opposes the first surface, and an electronic component is mounted in the cavity, and
wherein the hole is provided in a region of the first surface which opposes the cavity.

20. The circuit module according to claim 16, comprising:
a frame body on the first surface has a frame body, wherein the resin contacts the frame body, the first surface of the substrate, and the mounting component.

21. The circuit module according to claim 16,
wherein the display device is a liquid crystal display device.

22. An electronic device comprising the circuit module according to claim 16.
